(19) United States
(12) Patent Application Publication
(10) Pub. No.: US 2025/0273855 A1
(43) Pub. Date: Aug. 28, 2025

(54) RECONFIGURABLE INTELLIGENT SURFACES AND METHODS

(71) Applicant: DREXEL UNIVERSITY, Philadelphia, PA (US)

(72) Inventors: Kyei ANIM, Philadelphia, PA (US); Md Abu Saleh TAJIN, Millbourne, PA (US); Chelsea E. AMANATIDES, Philadelphia, PA (US); Genevieve DION, Philadelphia, PA (US); Kapil R. DANDEKAR, Philadelphia, PA (US)

(21) Appl. No.: 18/857,980

(22) PCT Filed: Apr. 18, 2023
(86) PCT No.: PCT/US2023/065917

§ 371 Date: Oct. 18, 2024

Related U.S. Application Data
(60) Provisional application No. 63/331,960, filed on Apr. 18, 2022.
(60) Provisional application No. 63/438,966, filed on Jan. 13, 2023.

(51) Int. Cl. H01Q 3/24; A41D 31/02; H01Q 1/27; H02J 50/00; H02J 50/27

(52) U.S. Cl. CPC H01Q 3/247; A41D 31/02; H01Q 1/273; H02J 50/001; H02J 50/27

(57) ABSTRACT

A functional fabric reconfigurable intelligent surface and communication system are disclosed.

### CROSS REFERENCE TO RELATED APPLICATIONS

The present application claims priority to and the benefit of U.S. Patent Application No. 63/331,960, “Reconfigurable Intelligent Surfaces and Methods” (filed Apr. 18, 2022), and U.S. Patent Application No. 63/438,966, “Reconfigurable Intelligent Surfaces Using Energy Harvesting” (filed Jan. 13, 2023), the entirety of which applications are incorporated herein by reference for any and all purposes.

### TECHNICAL FIELD

The present disclosure relates generally to communication systems and methods, and more particularly, to reconfigurable intelligent surfaces for controlling signal propagation.

### BACKGROUND

Reconfigurable intelligent surfaces (RISs) have been suggested as a promising new technology to enable NextG network systems. The idea behind RIS is that very large arrays of electrically switchable reflecting elements can be deployed in a given environment to effectively control the propagation channel between communicating nodes. The RIS can comprise metamaterials that are engineered to achieve functionality not found in naturally occurring materials. The new degree of freedom in the propagation channel can be utilized to provide “sculpting” of the power-delay profile between communicating nodes to, for example, increase received signal power to desired users, or limit received power to eavesdroppers. Existing research with RIS has largely considered their potential theoretical benefits without considering how they can be practically developed, manufactured, deployed, and controlled at scale in realistic settings using non-traditional materials (e.g., fabrics).

The information included in this Background section of the specification, including any references cited herein and any description or discussion thereof, is included for technical reference purposes only and is not to be regarded subject matter by which the scope of the invention is to be bound.

### SUMMARY

An aspect of the present disclosure provides a reconfigurable intelligent surface (RIS) for controlling propagation in a communication system. The RIS can include a plurality of switches, a first plurality of conductive fabrics, a second plurality of conductive fabrics, and a non-conductive fabric layer. Each one of the first plurality of conductive fabrics can be connected to another one of the first plurality of conductive fabrics by one switch of the plurality of switches. Each one of the second plurality of conductive fabrics can be connected to another one of the second plurality of conductive fabrics by one switch of the plurality of switches. The first plurality of conductive fabrics and the second plurality of conductive fabrics can be attached to the non-conductive fabric layer. The first plurality of conductive fabrics can be spaced from the second plurality of conductive fabrics.

Another aspect of the present disclosure provides a communication system. The communication system can include an RIS and a controller. The RIS can include a plurality of switches, a first plurality of conductive fabrics, a second plurality of conductive fabrics, and a non-conductive fabric layer. Each one of the first plurality of conductive fabrics can be connected to another one of the first plurality of conductive fabrics by one switch of the plurality of switches. Each one of the second plurality of conductive fabrics can be connected to another one of the second plurality of conductive fabrics by one switch of the plurality of switches. The first plurality of conductive fabrics and the second plurality of conductive fabrics can be attached to the non-conductive fabric layer. The first plurality of conductive fabrics can be spaced from the second plurality of conductive fabrics. The controller can be configured to transmit control signals to the plurality of switches to control propagation.

Further, the knowledge of incident power and relative phase distribution across an RIS can potentially simplify the state-selection process. Herein is presented a novel method of obtaining incident power and relative phase distribution using energy harvesting circuits (rectifiers) that can be integrated in the RIS. Four versions of the energy harvesting circuit are proposed that offer great control over the sensitivity of the system. The sensitivity of the proposed rectifier circuit is −42 dBm for direct rectification. The inclusion of direct current (DC) bias and radio frequency (RF) amplifiers greatly increases the sensitivity of the rectifiers. The received power and phase distribution across the unit dipoles of RIS are simulated to demonstrate the potential of the proposed method. Experiments are performed in an indoor environment at 2.1 GHz. Experimental results show that the proposed energy harvesting method can successfully predict the received power distribution for angular and perpendicular incidence of the incident radio waves.

In meeting the described long-felt needs, the present disclosure provides an intelligent system, comprising: a reconfigurable intelligent surface (RIS), the RIS comprising at least one energy harvesting circuit.

Also provided is an intelligent system, the intelligent system comprising a RIS as described herein.

Further provided is a method, comprising developing a harvested energy map or received power distribution of an intelligent system according to any one of Aspects 1-7.

This summary is not intended to identify key features or essential features of the claimed subject matter, nor is it intended to be used to limit the scope of the claimed subject matter. A more extensive presentation of features, details, utilities, and advantages of the present invention is provided in the following written description of various embodiments of the invention, illustrated in the accompanying drawings, and defined in the appended claims.

### BRIEF DESCRIPTION OF THE DRAWINGS

The file of this patent or application contains at least one drawing/photograph executed in color. Copies of this patent or patent application publication with color drawing(s)/photograph(s) will be provided by the Office upon request and payment of the necessary fee.

FIG. 1 illustrates a control architecture for a communication system, according to an aspect of this disclosure.

FIGS. 2 and 3 illustrate a knitted wearable strain sensing antennas for medical IoT applications, according to aspects of this disclosure

FIG. 4 illustrates a fabric-based reconfigurable intelligent surface (RIS), according to an aspect of this disclosure.

FIG. 5 illustrates a conceptual mockup of an IoT network, according to an aspect of this disclosure.

FIG. 6 illustrates a controller for an RIS-equipped environment, according to an aspect of this disclosure.

FIGS. 7A and 7B illustrate graphs of a changing state of an RIS in the environment illustrated in FIG. 6.

FIG. 8 illustrates schematics of reconfigurable antennas, according to aspects of this disclosure.

FIGS. 9A and 9B show an example of a decentralized control structure organized in hierarchical fashion.

FIGS. 10-28 provide example, non-limiting illustrations of the disclosed technology.

### DETAILED DESCRIPTION

Certain terminology used in this description is for convenience only and is not limiting. The words “top”, “bottom”, “leading”, “trailing”, “above”, “below”, “axial”, “transverse”, “circumferential,” and “radial” designate directions in the drawings to which reference is made. The term “substantially” is intended to mean considerable in extent or largely but not necessarily wholly that which is specified. All ranges disclosed herein are inclusive of the recited endpoint and independently combinable (for example, the range of “from 2 grams to 10 grams” is inclusive of the endpoints, 2 grams and 10 grams, and all the intermediate values). The terminology includes the above-listed words, derivatives thereof and words of similar import.

NextG network systems (6G, future WiFi, etc.) can be designed to accommodate an extremely large number of devices in a heterogeneous Internet of Things (IoT). The past several decades has seen a tremendous amount of research into all of the layers of the wireless network stack to optimize point-to-point throughput and manage limited spectral resources. However, when contemplating indoor IoT deployments with such extreme density supporting a wide variety of applications, flexibility is required not only in the protocol stack of the network nodes, but also in the radio frequency (RF) propagation environment.

RISs have been suggested as a promising new technology to enable NextG network systems. The core idea behind RIS is that very large arrays of electrically switchable reflecting elements can be deployed in a given environment to effectively control the propagation channel between communicating nodes. They can be considered to be metamaterials that are engineered to achieve functionality not found in naturally occurring materials. This new degree of freedom in the propagation channel can be utilized to provide “sculpting” of the power-delay profile between communicating nodes to, for example, increase received signal power to desired users, or limit received power to eavesdroppers. However, there are a number of challenges that can be confronted for RIS to become a practical technology for NextG communication systems:
Existing research with RIS has largely considered their potential theoretical benefits without considering how they can be practically developed, manufactured, deployed, and controlled at scale in realistic settings.
While software-defined radio (SDR) provide control knobs across the protocol stack inside of wireless network nodes, these degrees of freedom should be effectively integrated with the flexibility provided by RIS subject to constraints on channel estimation and control overhead.
Existing approaches with RIS are looking largely at received power maximization in point-to-point links and not other metrics provided by SDR across the protocol stack, as well as in more complex network topologies.

The communication system with RIS described herein is designed to: i.) develop a new kind of RIS using functional fabrics that can be integrated with a wide variety of household items (e.g., drapes, wall coverings, upholstery, carpeting), ii.) demonstrate how these RIS can be integrated with experimental SDR implementations to enable new applications for RIS in managing dense and complex IoT network topologies, and iii.) develop practical control algorithms for these pervasive RIS and IoT networking applications and demonstrate their performance in an indoor radio network testbed.

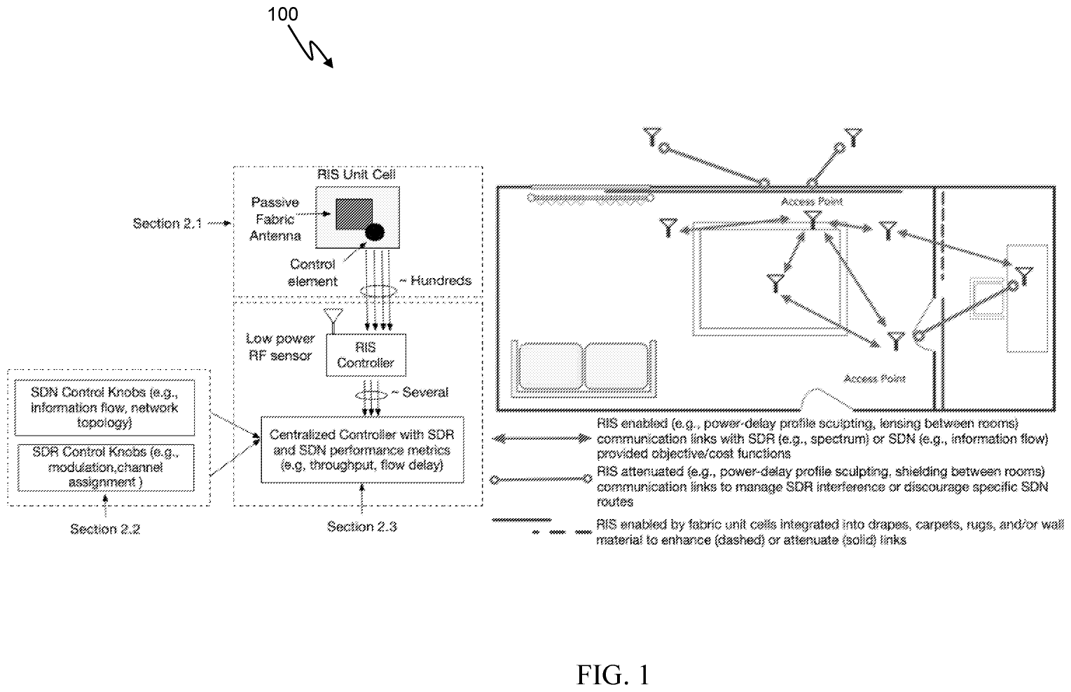

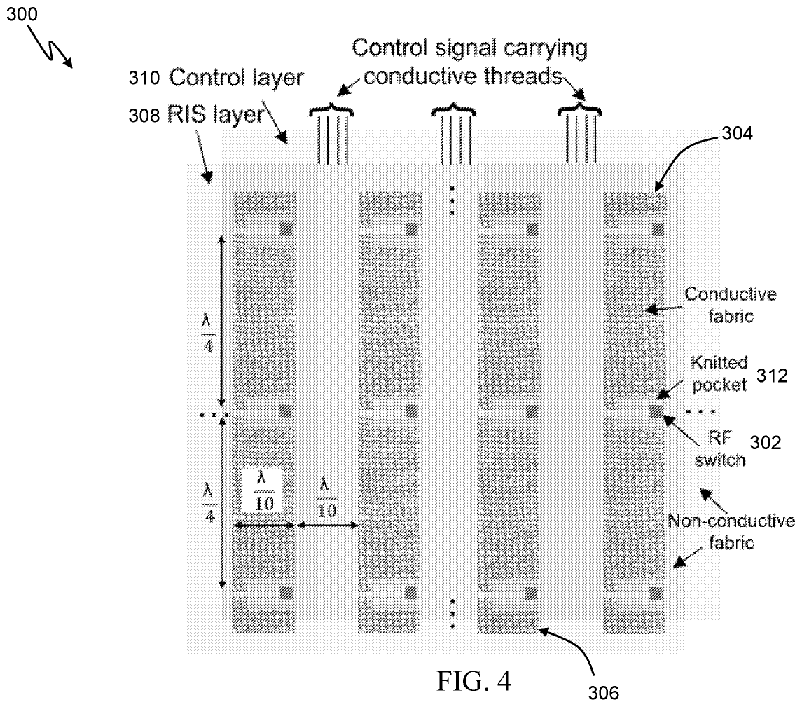

FIG. 1 illustrates a communication system 100 with a dense indoor IoT deployment with heterogeneous devices transmitting information using complex network topologies. FIG. 1 illustrates how the use of functional fabrics to realize RIS can enable pervasive and unobtrusive deployment of RIS in real environments, such as through integration into upholstery, drapery, and carpets (shown in FIG. 4). The RIS can comprise individually addressable and controllable units cells, each made up on fabric-based passive antenna and a discrete control element whose impedance state can be set in batches using low power and low-complexity RIS controllers, which in turn will be overseen by a centralized controller that can manage the network and control overhead while also coordinating with the multiple IoT access points in the environment to tune SDR (e.g., spectrum allocation, modulation, coding) degrees of freedom. A goal of the controllers is to leverage feedback from network nodes and limited distributed RF sensing in the environment, to achieve resilient and dense heterogeneous IoT deployments. The goal can be accomplished by, for example, setting the states of the RIS in the environment to: i.) proactively sculpt the power delay profile of network and interfering links to enable or enhance certain links (e.g., links illustrated in green), disable or attenuate other links (e.g., links illustrated in red) taking into account both spectrum utilization and information flow performance metrics. While explicitly obtaining training information for the propagation channel as a function of all possible RIS states can be infeasible, a decentralized control and learning algorithm for the proposed fabric RIS can demonstrate this technology on an experimental testbed. The intellectual merit and benefits of this disclosure includes, for example:

Design and Manufacturing of Functional Fabric RIS—Advanced manufacturing capabilities with functional fabrics can be applied to prototype and evaluate fabric-based RIS that can be pervasively and unobtrusively deployed in dense indoor IoT networks. The design can be evaluated and simulated through characterization in electromagnetic reverberation and anechoic chambers.

RIS Enabled with Cross Layer Networking—Unlike the vast majority of RIS research that considers the maximization of received power in point-to-point links, new RIS optimization approaches leveraging performance metrics from a SDR. These SDR control knobs and performance metrics can be integrated with the degrees of freedom provided by the RIS in the previous thrust, as well as iteratively inform the design of the functional fabric RIS. The proposed techniques can be evaluated in a software-defined radio network testbed.

Learning and Control for RIS State Selection—Integrating the results of the previous thrusts, practical control algorithms can be developed for the proposed dense IoT deployments with functional fabric RIS. How control and sensing should be distributed across the various entities (i.e., centralized controller, distributed low-power/complexity sensors, network nodes) in the proposed network can be determined based on past research in reconfigurable antenna machine learning, as well as distributed control, learning, and computation.

The design, advanced manufacturing, and evaluation of RIS using functional fabrics can align with BL:RF and mixed signal circuits, antennas and components technology. The vast majority of RIS research has been accomplished using printed circuit boards on planar structures, and this disclosure can fundamentally advance this field by enabling fabric-based RIS that can be unobtrusively, conformally, and pervasively deployed in real environments.

### 2 Intellectual Merit

### 2.1 Design and Manufacturing of Functional Fabric RIS

The implementation of RIS using a combination of conductive and non-conductive fabrics can provide many advantages over existing RIS approaches which make use of conventional printed circuit boards. The unobtrusive nature of these functional fabric RIS can enable them to be seamlessly integrated with everyday objects like drapes, wall/cubicle coverings, carpets, and upholstery—and thus provide potentially transformative technology commercialization avenues for NextG systems. Furthermore, the fabrication of the functional fabric RIS using industry-friendly automated advanced manufacturing techniques can enable them to be deployed at realistic scale.

To develop the proposed functional fabric RIS, the Drexel Center for Functional Fabrics (CFF) can be leveraged, which is a member of the nationwide Advanced Functional Fabrics of America (AFFOA) advanced manufacturing institute.

### 2.1.1 Background and Related Work

RIS research is still in its infancy and has been mostly limited to simulation and mathematical models. Only a handful of RISs have been practically fabricated and tested in laboratories. These existing RIS implementations make use of commercial radio frequency components and conventional printed circuit board fabrication techniques, limiting their flexibility and integration in everyday devices. There has not previously been any research involving the use of conductive fabric-based RIS.

The Center for Functional Fabrics at Drexel University has leveraged advanced manufacturing knitting machines to create textile devices with the potential for integration into the Internet of Things (IoT) ecosystem. Recent advancements in specialized materials and fabrication technologies offer exciting opportunities to design and knit seamless garments as sensors, actuators, and transceivers for smart textiles. These technologies also enable the development of larger textile systems, such as the proposed functional fabric RIS.

Knitting, known as the inter-meshing of yarns into loops (resulting in fabrics), is an ancient form of textile production widely used in the textile and fashion industry. Advancements in computer interfaced machine knitting have effectively transformed a centuries-old process into a scalable and mass customizable form of garment and textile manufacturing. Knitting technology has gained a lot of attention in the field of wearable electronics and is becoming a widespread method of construction for textiles of the future, due to the structure's inherent ability to create continuous electronic pathways within the knit structure itself. The knitting process offers the ability to control small scale stitch structure and large-scale form within a textile device, enabling seamless incorporation of electronics via hidden pockets (e.g., control elements of a functional fabric RIS) or new yarn materials embedded in the textile architecture (e.g., conductive thread for functional fabric RIS unit cells). For example, Shima Seiki knitting technology at Drexel University can enable customization and innovation in the design and fabrication of textile devices. This type of fabric production can offer huge savings in terms of manufacturing costs and significantly reduces material waste, enabling new design approaches and innovation in garment and product development. These technologies can be leveraged for material science, modeling, rapid prototyping, fabric-based connectors, microwave antennas, system integration and partnerships with leading research groups domestically and internationally.

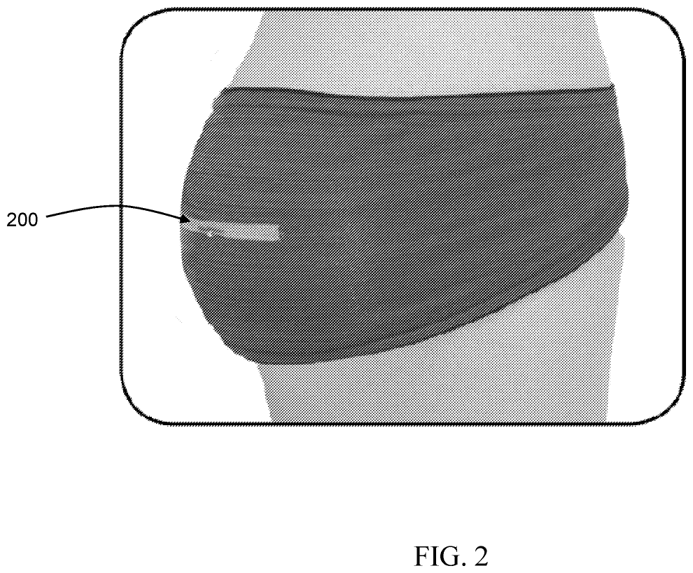

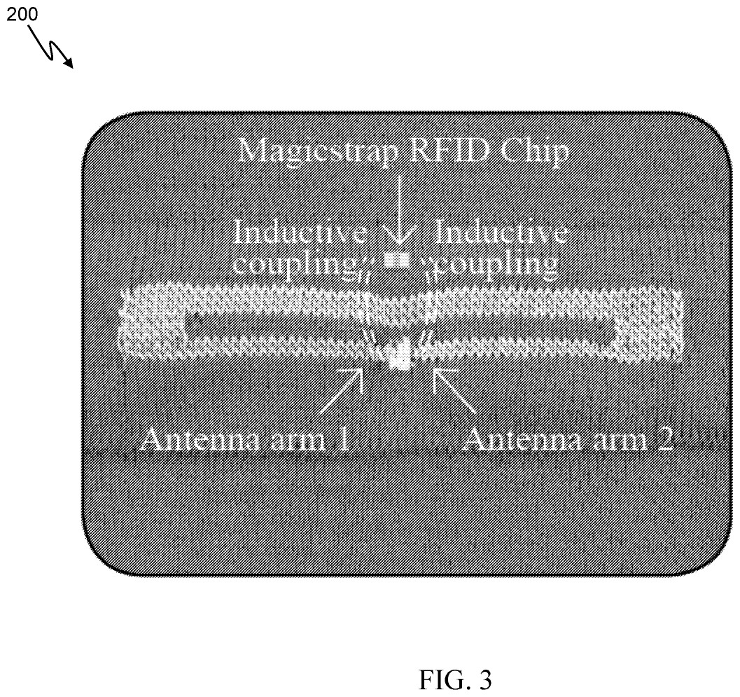

FIGS. 2 and 3 illustrate a knitted wearable strain sensing antennas (Bellyband) 200 in the RFID band (902-928 MHz) for medical IoT applications. A variety of fabric designs have been explored regarding conductive yarn materials, and the effects on device performance have been investigated, as well as impacts factors such as sweat exposure and laundering. Free-space and on-body radiation efficiency of the Bellyband antenna 200 was measured in anechoic and electromagnetic reverberation chambers. Radiation efficiency of omnidirectional folded dipole antennas drop sharply in the presence of body tissue. As a result, the read range of the passive RFID antenna is severely restricted (e.g., 3 feet). To alleviate the problem, a novel knitted RFID compression sensor is used that shows good radiation efficiency and read range (e.g., 20 feet) in both free space and on-body. This analysis can be leveraged to develop functional fabric RIS that can be designed to operate effectively under different levels of mechanical deformation and realistic near-field scattering scenarios (e.g., from the human body).

Knitted conductive fabrics can include interlocked series of conductive material-coated non-conductive threads. Due to the complex geometry and yarn material variations, it is infeasible to simulate knitted conductive fabric-based RF structures, such as the proposed functional fabric RIS, using electromagnetic simulators (e.g., HFSS, CST, etc.). An alternative to conductive and thickness-based simulation is the use of 2D structures with assigned sheet resistance. A method for measuring RF sheet resistance of conductive surfaces includes, for example, extracting RF sheet resistance of conductive knitted surfaces from 2-port transmission line scattering parameter measurements. These integrated characterization and simulation tools can be applied towards the design and implementation of functional fabric-based RIS.

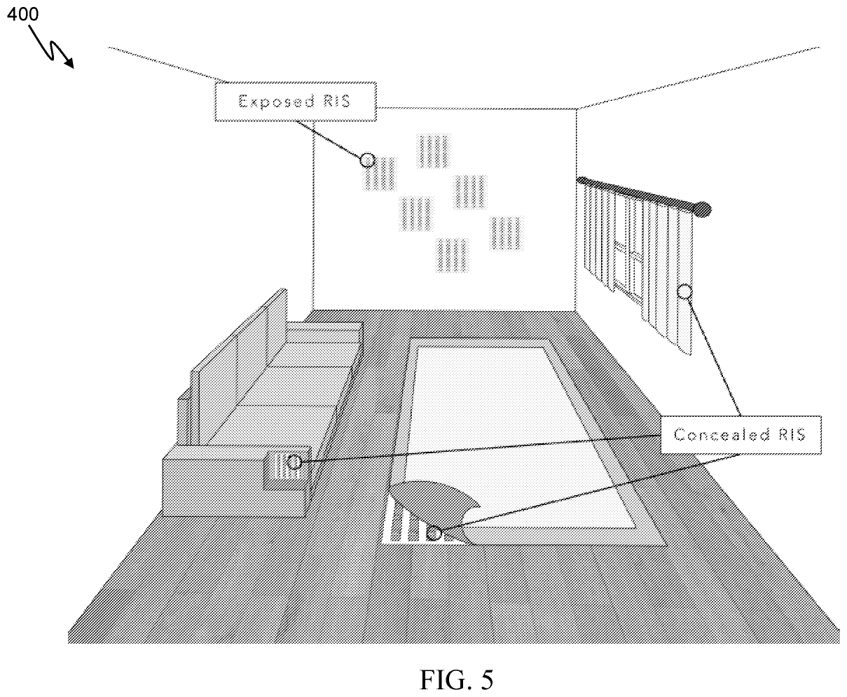

FIG. 4 illustrates a fabric-based reconfigurable intelligent surface (RIS) 300 that includes multiple layers for the surface as well as for control signal distribution, and FIG. 5 illustrates a conceptual mock-up of an IoT network 400 showing the concealed or exposed integration of the fabric-based RIS 300 in everyday objects. The RIS 300 is part of the communication system 100.

The RIS 300 includes a plurality of switches 302, a first plurality of conductive fabrics 304, a second plurality of conductive fabrics 306, an RIS layer 308, and a control layer 310. In an aspect, the RIS layer 308 and the control layer 310 are non-conductive. Each of the first plurality of conductive fabrics 304 is connected to at least one other fabric of the first plurality of conductive fabrics 304 by one of the plurality of switches 302. In an aspect, the first plurality of conductive fabrics 304 is connected in series with one switch of the plurality of switches 302 connected between each of the first plurality of conductive fibers 304. Similarly, each of the second plurality of conductive fabrics 306 is connected to at least one other fabric of the second plurality of conductive fabrics 306 by one of the plurality of switches 302. In an aspect, the second plurality of conductive fabrics 306 is connected in series with one switch of the plurality of switches 302 connected between each of the second plurality of conductive fibers 306.

The first and second plurality of conductive fabrics 304 and 306 can be attached to the RIS layer 308. In an aspect, both of the first plurality of conductive fabrics 302 and the second plurality of conductive fabrics 306 comprise knitted conductive fabrics. The first plurality of conductive fabrics 304 can be spaced from the second plurality of conductive fabrics 306 on the RIS layer 308. The RIS layer 308 can be positioned in contact with the control layer 310. In an aspect, the RIS layer 308 is positioned between first and second plurality of conductive fabrics 304 and 306 and the control layer 310. In an aspect, both of the first plurality of conductive fabrics 304 and the second plurality of conductive fabrics 306 are knitted to the RIS layer 308.

Each of the first plurality of conductive fabrics 304 can include at least one pocket 312. Similarly, each of the second plurality of conductive fabrics 306 can include the at least one pocket 312. Each pocket 312 can include one switch of the plurality of switches 302 attached thereto. In an aspect, each pocket 312 comprises a knitted pocket.

Each of the plurality of switches 302 is wirelessly controlled by the communication system 100. For example, each switch 302 can receive a signal via the communication system 100 to transition between open and closed positions. The control layer 310 can include a plurality of conductive threads configured to carry control signals to the plurality of switches 302.

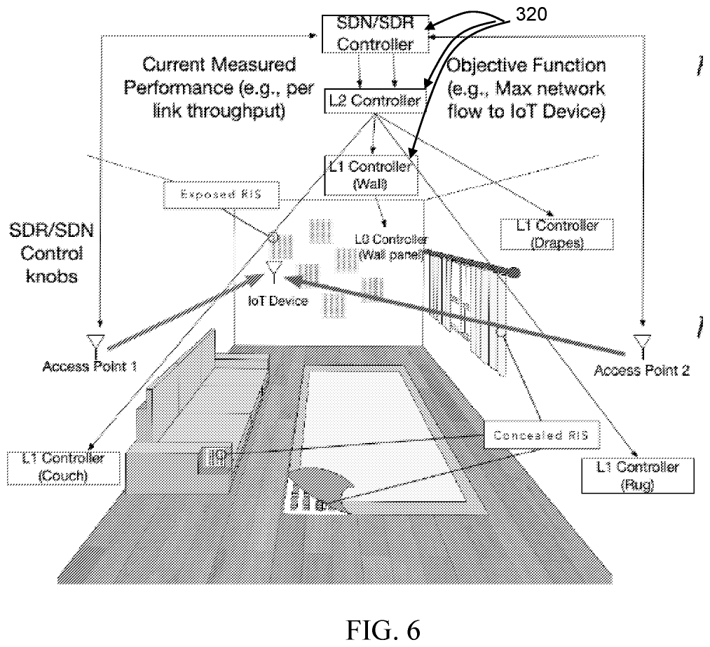

The communication system 100 further includes at least one controller 320 (see FIG. 6). The controller 320 is configured to transmit control signals to the plurality of switches 302 to control propagation. In an aspect, the controller 320 transmits the control signals to the plurality of switches 302 to affect an impedance of the RIS 300. The controller 320 can include, for example, a transmitter configured to transmit a signal, and a receiver configured to receive the signal via the RIS 300.

Sub-task 1.1: The fabrication of the functional fabric RIS 300 can start with the selection of the best available knitted conductive fabric. A preliminary design for the proposed fabric RIS 300 is shown in FIG. 4. An understanding of the electromagnetic characteristics of fabric-based structures can help in the design of fabric based RIS. Although DC sheet resistance of a conductive fabric can be measured, it does not represent the complete perspective. The main reason is that conductive fabrics have random distribution of conductive flakes instead of continuous structures as one would find on conventional printed circuit boards. The inter-flake separation does not allow the flow of DC. Nevertheless, there are a few connected DC pathways between two points in the fabric. The DC discontinuities are short-circuited at RF. Moreover, depending on the knit pattern, the fabric can have different RF performance. Thus, it is important to appreciate that conventional printed circuit board RF design tools may not be directly applicable to knitted conductive fabric radiators. These challenges can be addressed by jointly considering electromagnetic performance with the parameters of the knitting fabrication system (e.g., conductive/non-conductive yarn selection, number of yarn carriers for different designs, tightness of knitted loops, knitted patterns, integration of materials to increase flexibility). Using this approach, on-body fabric antennas can be characterized with well understood electromagnetic properties to operate in the presence of a human body. The preliminary design can be refined, as shown in FIG. 4, toward practical deployment. A challenge that may need to be addressed is in the development of conductive fabric to circuit interconnects to realize unit cells with external circuit control. This challenge can be addressed by using knit pockets to house chips or small circuit boards. Thus, the controllable functional fabric RIS unit cells can be designed using this interconnect and RF characterization, as well as a scalable manufacturing process for large-scale production of fabric RIS.

Sub-task 1.2: Small groupings of the fabric RIS unit cells from the previous task can be manufactured to be evaluated in electromagnetic anechoic and reverberation chambers to refine and validate simulation models that can be used to identify promising designs. Small scale electromagnetic chamber testing can allow how RIS can be experimentally characterized and can be used to effectively “sculpt” the power delay profile in individual channels and, at slightly larger scale, dynamically adjust the Quality (Q)-factor of rooms modeled as microwave cavities. This Q-factor modeling of indoor spaces can be linked to communication system performance and associated link-adaptive signaling, as was done in “An empirical study on the performance of wireless OFDM communications in highly reverberant environments,” IEEE Transactions on Wireless Communications, vol. 15, pp. 4802-4812, July 2016. Specifically, in this reference, the link adaptive modulation performance could be linked to the Q-factor of industrial IoT environments. This technique can be applied to design SDR approaches making use of functional fabric RIS which is intentionally changing the Q-factor. With larger functional fabric RIS prototypes, a challenge in this task can be to develop a signal bus in fabric to effectively route control signals to each unit cell, illustrated in FIG. 4. This challenge can be addressed by routing baseband control signals in fabric, which is much easier than our RF applications of conductive fabrics, and developing a multi-layer fabric RIS that has a dedicated layer in fabric to efficiently deliver control signals to their desired unit cell destinations, as shown in FIG. 4. Promising designs from this process can be used for future scale-up as well as provide the underlying models for hardware emulation testbeds for control algorithm development.

In order to collect large amounts of training data to design learning and control algorithms for the fabric RIS, the ability to simulate the electromagnetic propagation channel of the fabric RIS while it is in different states is needed. Remcom Wireless InSite (https://www.remcom.com/wireless-insite-em-propagation-software) is a popular ray-tracing tool that can be used in the past for propagation modeling and integration with large scale wireless channel emulation, that has also recently been extended towards simulating the wireless channels in the presence of RISs. It allows the creation of virtual environments at different scales (e.g., a living room or an urban area) consisting of different objects and materials. Each material is defined by its electrical properties (e.g., conductivity, relative permittivity, relative permeability, loss tangent). Transmitter and receiver antennas can be placed with great control and flexibility on their orientation and properties. The simulation of a fabric RIS is different compared to objects with materials of known electrical properties. Fortunately, a method was developed for the extraction of RF sheet resistance of conductive surfaces, which can play a crucial role in the electromagnetic simulation of fabric RISs. The extracted RF sheet impedance of the conductive fabric can be used to convert the conductive fabric into a material with an equivalent conductivity and thickness. A computer-aided design (CAD) model can be developed of the RIS geometry at the state of interest using the equivalent conductive and thickness data. By placing the CAD model of the RIS in the virtual environment along with the transmitting and receiving antennas, the channels of the RIS can be simulated.

Sub-task 1.3: Industrial knitting machine technologies, such as those available at the Drexel CFF, offer a range of fabric formation techniques that can be deployed to develop functional fabric RIS. Intarsia knitting allows for multiple yarn materials to be incorporated into a single layer of fabric, with each material prescribed to a specific region of the fabric in a customizable manner. The use of this technique can be used to develop reconfigurable textile antennas. The maximum width of these fabrics, and number of fabric RIS unit cells can correspond to the width of the knitting machine used for fabrication; however the length of these fabrics does not need to be limited as fabric could be produced in continuous lengths, many meters long. In this way, this technology can be applied in a similar way to wallpaper, where it is sourced in rolls, and applied to a wall in columns as needed to fit the space. Alternatively, a semisoft tiling system can be used, with panels that connect into a larger system. This method affords opportunity for customization, through placement of tiles in patterns, and combinations of tiles made with different color yarns. Additionally, using the 3D shaping capabilities of industrial knitting's machines, similar intarsia structures can be created on fabrics that conform to the shape and size of furniture such as couches. This is an important capability to emphasize, as the vast majority of RIS research to date have focused on planar, rather than conformal, surfaces.

Other advantages of this approach include the possibility of developing multilayer fabrics using a single manufacturing process. This can allow for the antenna structure on one layer of the fabric, while the second layer of the fabric could be utilized for creating knitted electronic traces, to connect to a control signal bus, or other RIS units. The use of multiple layers allows not only for electrical separation where necessary, but also the ability to adjust the fabric surface to suit the aesthetics of a particular space. These textiles could also be assembled into systems with non-conductive textile overlays, allowing for the technology to serve as a design feature, or be completely hidden, as desired for a particular space. FIG. 4 shows a mockup of a living room featuring both exposed and hidden functional fabric RIS.

2.2 RIS Enabled with Cross Layer Networking

Most previous research with RIS is focused on optimizing received power, or adjusting MIMO channel quality, for individual links in a network. In this disclosure, the fabric RIS can be integrated with a controller that has access to control knobs and performance metrics provided by SDR and SDN. Specifically, the selection of fabric RIS state can be coordinated with cross-layer control algorithms for applications such as link adaptive modulation and coding, spectrum management, link-adaptive routing, and network information flow control.

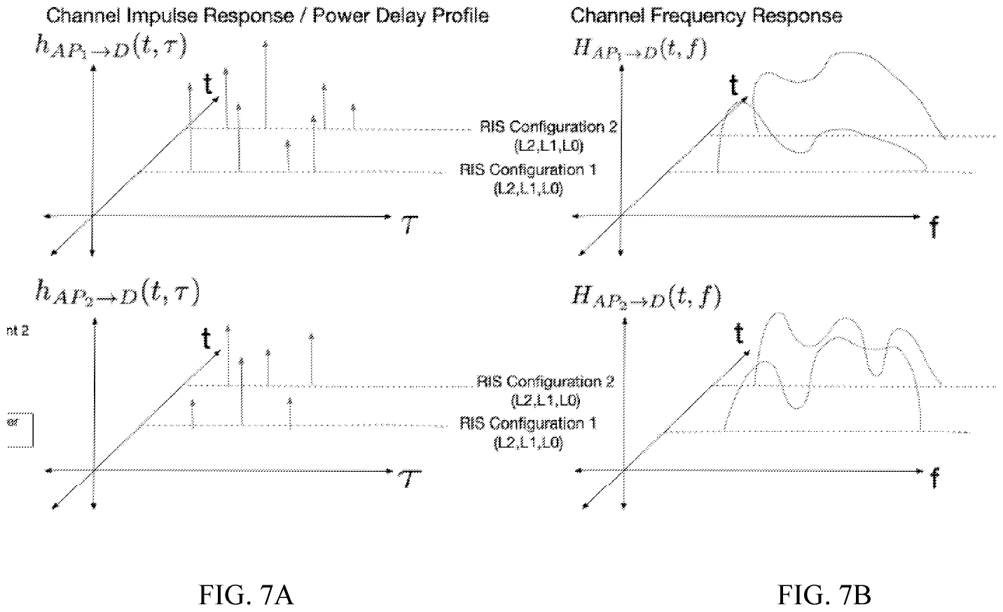

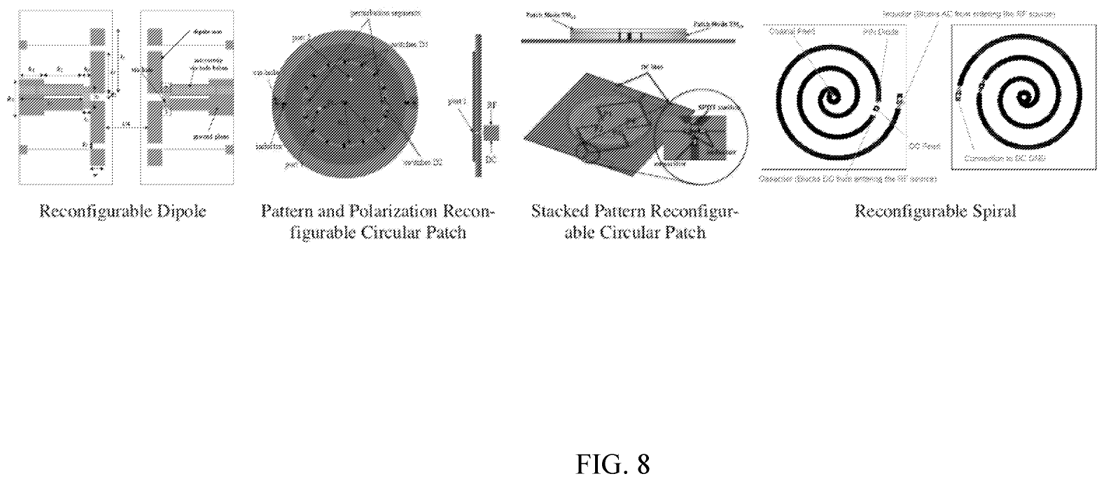

FIG. 6 illustrates the controller 320 i.) collecting and distributing information on the overall objective function (e.g., maximize network flow to IoT device) as well as SDR performance metrics (e.g., per link throughput), ii.) adjusting SDR control knobs (e.g., PHY OFDM adaptive modulation, OFDMA subcarrier assignments, TDMA/FDMA MAC schedules), and iii.) selecting fabric RIS unit cell configurations in a room. The controller 320 can comprise a hierarchical controller. FIG. 7A illustrates changing the state of the fabric RIS 300 in the room creates adjustable channel impulse response of links within the space that when Fourier transformed provides (FIG. 7B) controllable channel frequency response. Thus, RIS 300 enables adjustable and controllable frequency selective channels that can be exploited for link adaptive OFDM between links and/or OFDMA to allocate different subcarrier subsets to different links. The RIS 300 can be integrated into various fabrics, including, for example, a drape, a wall covering, an upholstery, a carpet, or still other fabrics.

### 2.2.1 Background and Related Work

SDR for NextG IoT The promise of SDR involves using a software reconfigurable protocol stack implemented on general purpose radio frequency transceiver hardware. Cognitive radio leverages the flexibility provided by SDR to use biologically inspired algorithms to sense the surrounding radio environment and adapt the radio (i.e., typically spectrum allocation) to changing link and network conditions. Both SDR and cognitive radios are ideal tools for prototyping of future communication standards and techniques since they are not limited by the constraints imposed by commercial products. In the context of NextG IoT networks, the flexibility of cognitive radio can be required for dense, spatially separated IoT nodes to operate in a harsh and crowded radio frequency spectrum. However, unlike the vast majority of previous cognitive radio research, these NextG cognitive IoT networks can be required to operate with highly limited power and processing constraints. However, NextG cognitive IoT networks can also have access to the capabilities of the proposed fabric RIS to reduce the power and processing demands on individual IoT devices.

In this disclosure, prototyping on a flexible SDR platform can allow control knobs and performance metrics to be exposed that can be integrated with RIS controllers to develop link adaptation, spectrum management, and adaptive routing techniques that not only tune and optimize the parameters of the radio, but also make use of (limited) control over the propagation channel. The performance improvement of including fabric RIS in these NextG cognitive IoT networks can be quantified. The RIS can enable low power and low-processing NextG IoT networks to operate in environments that would not be possible without RIS. SDR control knobs and performance metrics can be identified that can be shared with the RIS controller to minimize network overhead and control.

While SDR can provide for programmability across the protocol stack within network nodes, the effective integration of SDR with the flexibility provided by RIS, subject to control overhead, has not been investigated before, and constitutes an important step for RIS to become a practical technology for NextG communication systems. Fabric RIS channel characteristics can be manipulated through the RIS controller, which can improve the propagation conditions, enrich the communication channel, and save energy consumption—which provides profound potential in IoT communication areas, especially when coupled with SDR integration to allow for RIS enabling in the MAC layer and benefits at higher layers. Each element in an RIS can be controlled to intelligently adjust the amplitude and/or phase of incoming electromagnetic waves, thus, rendering the direction and strength of the wave highly controllable at the receivers. This feature can be exploited to add different signals constructively/destructively to enhance/weaken their overall strength at different receivers. Thus, RISs can be used to enhance SNR, data rate, security, coverage probability, etc.

Dragon Radio Integration of fabric RIS into SDR comprises a cross-stack radio that exposes control knobs and performance metrics at all layers of the protocol stack. In this disclosure, a modular, efficient “canned” radio implementation, DragonRadio can be utilized. This radio system has been made open source and is currently available for use in the NSF PAWR Colosseum.

The radio makes extensive use of both parallelism and concurrency. For example, a bank of demodulator threads acts in parallel to demodulate multiple radio channels simultaneously, and C++ atomics are used to coordinate concurrent radio signal reception and demodulation. In the developed hybrid FDMA/Time Division Multiple Access (TDMA) MAC, parallelism enables frequency diversity, and concurrency decreases latency because demodulators do not need to wait for an entire TDMA slot's worth of data to have been received before demodulation can begin.

The physical layer of DragonRadio is based on the open-source liquid-dsp communications signal processing framework, which provides well-tested modem functions for Fourier-based multi-carrier modulations (OFDM) as well as single-carrier QAM and GMSK. It also includes an interface to an open-source Forward Error Correction (FEC) library. In an aspect, liquid-dsp is selected over GNU Radio as the basis of DragonRadio because of the full control over scheduling, data flow, and transmission timing. The physical, MAC, and datalink layers of the radio can be written in C++. This functionality is exposed to Python via pybind11, allowing control and spectrum sharing policies to be implemented in a high-level language.

### 2.2.2 Research Plan

Sub-task 2.1: SDR Integration with RIS: DragonRadio provides a highly-configurable infrastructure for collecting and logging its own radio metrics ranging over the complete radio stack all the way from the physical layer up to per-flow network packet loss and throughput on a configurable time scale. These metrics can be both logged and used at run-time to drive radio operation. It is also possible to perform real-time IQ collection over the entire receive bandwidth concurrent with demodulation without impacting radio performance; this allows a radio to take a “snapshot” of the IQ spectrum over a user-specified time window and then perform analysis of the IQ data, which is timestamped and annotated with the time and frequency occupancy of all transmitted and demodulated packets. When DragonRadio's OFDM physical layer is used, its channel coefficients can also be exposed and collected. These metrics provide a rich set of data for the controller developed in Section 2.3. Initially, these metrics will be provided to the controller at full rate over a wired network connection. Subsequently, a high-level network protocol is designed that allows the controller to specify what metrics to collect as well as the rate of data collection—“control knobs” can be implemented that allow the controller to trade data precision and data rate for network bandwidth. This introduces another level of optimization complexity—the controller can decide if the cost of data acquisition that might allow better overall network optimization will be offset by the additional throughput this data might enable.

This thrust will also investigate how the PHY and MAC layers of the radio can take advantage of RIS. Existing theoretical work indicates that an OFDM PHY can leverage RIS to optimize received signal power. A practical implementation of these ideas can be inputted in a version of the DragonRadio OFDM PHY modified to support multiple access (OFDMA). The underlying idea behind this theoretical work is that the OFDM PHY layer can use channel estimates to optimize signal power by manipulating the RIS. This same principal can also be used to optimize signal power across channels in an FDMA MAC, the primary difference being that the MAC channels have a much larger bandwidth than OFDM subcarriers. The DragonRadio hybrid TDMA/FDMA MAC can be used to incorporate these ideas as well to yield a combined PHY/MAC that can utilize RIS to optimize signal power across both small-scale (OFDM subcarrier) and medium-scale (FDMA channel) frequency ranges.

The end goal is to incorporate channel response prediction into a control model. This will allow the controller to predict how an RIS configuration will affect the RF environment, which can then be used by the controller to configure the DragonRadio PHY/MAC to meet network traffic goals.

Sub-task 2.2: Testbed Evaluation of RIS: As described in Section 2.1, knitted fabrication capabilities can be utilized to manufacture the proposed fabric RIS. After small scale testing of fabric RIS with anechoic and reverberation chamber, as well as in over the air lab benchtop testing, the proposed technology can be evaluated at a larger scale with a network of software defined radios. Specifically, in order to evaluate the developed fabric RIS with real radios, “curtains” of fabric RIS can be fabricated to integrate with the Drexel Grid SDR Testbed. Fabric RIS “curtains” can be made to hang from the same ceiling scaffolding system housing the radios. Thus, the curtains can be rapidly deployed in different physical configurations to the radios. The SDRs in the testbed also make use of electrically recconfigurable beam-steerable antennas that can be used in an array configuration. The use of both directional beamforming as well as how properties of multiple input multiple output (MIMO) channels (e.g., channel rank, invertibility) encountered in OTA testing can be controlled through modification of fabric RIS state can be examined. An advantage of the testbed approach is that the use of large scale wireless channel emulation can allow exposure of the SDRs to emulated fabric-RIS channels to consider how real radios would interact with real, computational electromagnetically simulated, and theoretical fabric RIS by changing the underlying channel model in the emulator. Furthermore, the emulation testbed is able to generate a large amount of sensor data in a limited time period. Machine learning techniques used in wireless IoT can be greatly enhanced by a large amount of data extracted from the emulation of dynamic and challenging environments. The multi-channel emulation testbed is therefore a valuable solution for experimentation on real hardware and a convenient tool for creating repeatable channel scenarios and producing large amount of data for the evaluation of RIS state selection algorithms.

### 2.3 Learning and Control for RIS State Selection

As shown in FIG. 1, the control architecture where there is a centralized controller overseeing both i.) NextG IoT access points with SDR/SDN capabilities (from the previous thrust), and ii.) distributed low-cost and low-power RIS controllers associated with logical groupings of RIS unit cells (e.g., one for a set of drapes, another for upholstery on furniture) that have limited RF sensing and processing capabilities.

RIS control can be very challenging because the number of unit cells containing control elements can be very large. For example, using the fabric RIS 300 shown in FIG. 4 that could be integrated in everyday objects like wall coverings, upholstery, and carpets can result in hundreds of fabric RIS unit cells that need to be controlled. While distributed RIS controllers can be on each every day object, even if the control elements in each unit cell has only have two potential states for “on” and “off”, the search space over all possible configurations for a room can be enormous. Furthermore, it may be impractical to explicitly collect channel training data over all possible fabric RIS configurations since the time required to do so, would be greater than the coherence time of the channel. Thus, heuristic based solutions using reinforcement learning that controls RIS unit cells in batches can be used rather than individually. In this disclosure, the approach for controlling fabric RIS state selection (integrated, and informed by SDR/SDN degrees of freedom identified in the previous thrust) is cognizant of these challenges but seeks to balance: i.) fine grained control theoretically possible with pervasive fabric RIS deployment with ii.) the exchange of state information between centralized controller, distributed (low complexity and low power) RIS controllers, and the NextG IoT access points operating in a given environment.

### 2.3.1 Background and Related Work

Previous RIS State Selection Channel estimation in RIS based systems is often done under tightly controlled RIS physical deployments or in largely theoretical or simulation-based studies with significant underlying assumptions about the statistics, structure, and stability of the wireless channel.

There are a limited number of experimental or testbed deployments of RIS that make use of practical control algorithms, as described in this disclosure. However, many of these initial demonstrations have been at small scale demonstrating received power optimization in point-to-point links. There has been some testing at larger scale, but again this research was focused on enhancing received power without considering higher layer network metrics.

The use of reconfigurable antennas are a natural complement to the capabilities provided by the fabric RIS. Reconfigurable antennas allow for beams to be dynamically steered in response to the needs of the overlying link and network. Reinforcement learning using the multi-armed bandit and adaptive pursuit for re-configurable antenna state selection can be used. While these approaches are not directly applicable to the fabric RIS since the search space is much larger, they do provide good starting points for heuristics jointly controlling reconfigurable antennas on the NextG IoT nodes with the proposed fabric RIS. These reconfigurable antenna beams can be used to illuminate specific panels of fabric RIS and thus better coordinate the operation of the radio and fabric RIS. Specifically, rather than controlling random subsets of fabric RIS to try to influence a particular communication channel, knowledge of the state of the beamforming reconfigurable transmitter and receiver and locations of the fabric RIS deployed in the environment, can allow for the most impactful (i.e., in terms of effect on the propagation channel) RIS elements to be identified.

### 2.3.2 Research Plan

Q-learning is a reinforcement learning technique used to find the optimum policy of a given Markov Decision Process (MDP). The algorithm includes a learning agent that works by observing the state (s) of the environment and selecting a suitable action (a) to control the state. Learning is quantified and stored in a table (referred to as Q-Table in machine learning terminology) corresponding to every state-action pair. Each entry of this table, corresponding to the state-action pair (s; a), represents the reward (or penalty, if the entry is negative) obtained by selecting action a when the environment is in state s. The algorithm works by always selecting the action with the highest reward for any observed state of the environment.

Model-free Q-learning is responsible for updating the Q-Table entries at the end of each epoch. The reward or penalty for selecting an action at a state is calculated at the end of the next epoch based on the goodness of the selected action. In other words, at each epoch, the state-action pair of the last epoch is evaluated. The goodness of the last action in the last state is measured as a reward (positive) or penalty (negative) and is stored in the Q-table. However, Q-learning is associated with some key limitations when applied in the context of controlling multiple RIS. For instance, with N RIS (each configured to be in ON or OFF state), there are 2N possible actions. Similarly, the number of states with these N RIS can be significantly higher. Therefore, the Q-table size is 2N×M, where M is the number of states of the control system. For the algorithm to converge, a significant amount of training data needs to be generated. Additionally, there is a large overhead associated with storing the Q-table and updating it at every epoch.

Therefore, in addition to exploring the tradeoffs associated with Q-learning, in an aspect, a decentralized structure to control multiple RIS as described in the following sub-tasks can be developed.

Sub-task 3.1: Cost/Objective Function Design: A challenge to be considered is the design of cost/objective functions that represent NextG IoT systems that leverages the degrees of freedom provided by the fabric RIS, SDR, and SDN. Consider a motivating example with co-existing environmental sensing (i.e., temperature, humidity, air quality) and medical (i.e., heart rate, respiration, COVID-19 localization contact tracing) IoT networks being served by the access points in the fabric RIS-equipped environment shown in FIG. 6. The controller receives SDR and SDN-related state information from the access points in the environment such as directions of beam-steerable access point antennas, time/frequency allocations, link throughput, packet loss rate, and information flow quality of service. It also receives data from the RF sensor integrated on each one of the controllers. An illustrative example using this network can involve a multi-objective function that would prioritize traffic flows, optimize throughput, and reduce packet loss rate of the medical IoT data while placing lower priority on the environmental sensing IoT devices. The hierarchical control process described in the subsequent tasks can be fed information on the current state of the network (e.g., RIS state, SDR/SDN control knobs, RF sensor data), information on the overall multi-objective function of the network, and performance metrics related to the current evaluation of the multi-objective function. Decisions to optimize the multi-objective function can involve: i.) setting the state of the fabric RIS in a decentralized ad hierarchical manner (described below), using information on which fabric RIS states are more impactful on specific communication links (e.g., using prior experience, and from knowledge of beamsteering directions of access point antennas), ii.) adjusting SDR operating parameters (e.g., adaptive modulation, spectrum allocation, OFDMA sub-carrier assignments), as well as iii.) adjusting SDN operating parameters (e.g., traffic forwarding rules, priorities, latency). Multi-objective functions can be investigated to determine what kinds are desirable towards creating resilient NextG IoT applications and quantify the sensitivity of different objective functions to fabric RIS design (Thrust 1), and the connection and potential coordination between RIS-adjustable channels and specific SDR/SDN degrees of freedom.

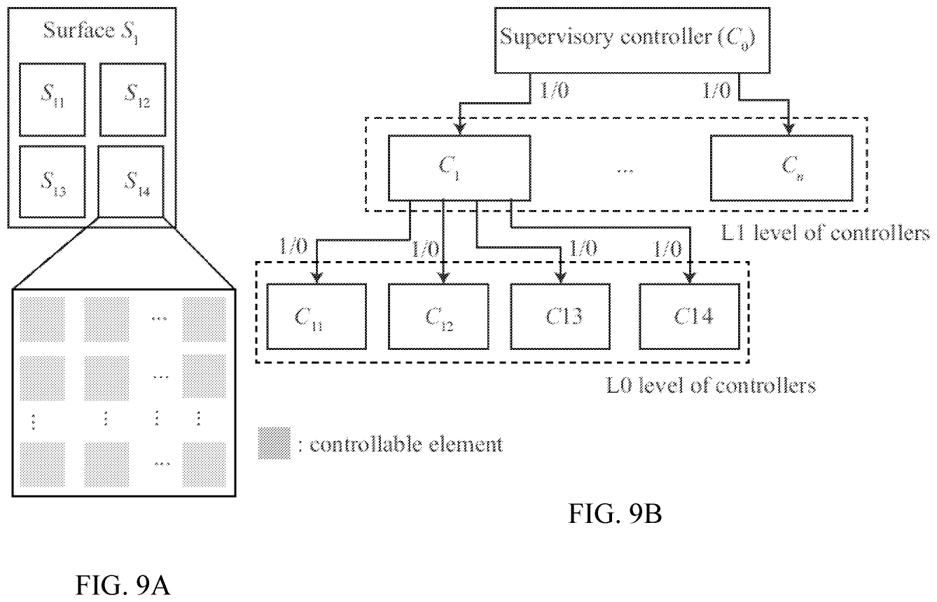

Sub-task 3.2: Decentralized Control of RIS State: Control of multiple RIS is posed as an online optimization problem in terms of the cost/performance metrics. Significant challenges should be addressed to achieve real-time control of a large-scale RIS system with multiple interacting components. For an optimization scheme to be of practical value in such a distributed setting, it must tackle the “curse” of dimensionality the number of available tuning options is quite large and the corresponding search space grows exponentially with each new variable, making centralized controller designs intractable. Fortunately, control theory provides techniques that can reduce the computational burden of managing large-scale systems. In an aspect, the method is to structure controllers in decentralized fashion wherein the overall problem is decomposed into a set of simpler subproblems and solved cooperatively by multiple controllers. FIGS. 9A and 9B show an example of a decentralized control structure organized in hierarchical fashion. Here, a controller is responsible for only optimizing the behavior of component(s) under its control while satisfying the constraints imposed on it by a higher-level controller. The RIS system comprises of multiple controllable surfaces S₁, S₂, . . . , Sₙ, one of which is shown in FIG. 9A. Each surface is organized as a n×n grid of individually controllable conductive-fabric elements. Controllers interact as follows:
Given a configuration X_{L2}(t) in which individual surfaces are completely turned on or off, during each sampling step t_{L2}, the supervisor or L2 controller perturbs this state to generate k “neighboring” states—along the lines of a hill-climbing algorithm. For example, if the state at time t of a system with four surfaces is X(t)={1, 0, 1, 0}, that is S₁ and S₃ are on whereas S₂ and S₄ are off, the controller can generate {1, 0, 1, 1} and {1, 1, 1, 0} as k=2 possible neighboring states. It then measures—by actually setting the surfaces to these values—the performance achieved by each of the generated states over a period of time with respect to the baseline case in which all surfaces are turned off. (Performance of the baseline system can be quantified prior to deploying the RIS.) Configurations that perform worse than the baseline are discarded and the best-performing configuration among the rest is chosen as the one to maintain during the time interval t+t_{L2}.
The L1 controller tunes the performance of a single surface under the constraints set by the L2 controller (which operates at a coarse granularity). If its surface is turned off, the L1 controller remains idle. If the surface is turned on, then the L1 controller's responsibility is to optimize its performance. A surface itself may be partitioned into multiple sub-surfaces for the purposes of scalable control, as shown in FIGS. 9A and 9B. Each of these sub-surfaces can be turned on or off in their entirety by the L1 controller, the performance measured, and the best configuration provided as the constraint to the lowest-level controllers.
At the lowest level, the L0 controller switches on/off individual elements under its control using the following algorithm. Assuming n elements under its control and starting from the current configuration in which each element can be on/off, the controller generates k configurations of the form {s₀, s₁, . . . , sₙ₋₁, where sᵢ denotes the state of the i^{th} element. The controller evaluates the performance of each configuration with respect to baseline. It decides to turn on the i^{th} element for the next time step if for the majority of the k configurations, system performance is better than baseline when element i is on; else the element is turned off for the next time step.

Controllers at various levels of the hierarchy can operate at different time scales; since the L2 controller uses the aggregate behavior of lower-level controllers to make decisions, it typically operates on a longer time scale when compared to L1 and L0 controllers. The above-described control logic can incur low computational overhead. It is a metaheuristic in that it may provide a sufficiently good solution to the underlying optimization problem. It makes no assumptions about the structure of the problem and can search very large spaces of candidate solutions. It does not guarantee that an optimal solution will be found. For small problems sizes, however, its performance can be compared against the optimal solution.

Sub-task 3.3: Approximation Modeling for Online Performance Management: The hierarchical structure in FIGS. 9A and 9B can be operated more efficiently and control decisions issued much faster if each high-level controller had a behavioral model of the components comprising the immediate lower level. Concepts from approximation theory can be used to further reduce the computational burden of controlling the nonlinear system. The relevant approximations can be made in the construction of dynamical models to predict system behavior. For example, to determine which surfaces to turn on/off, the L2 controller must be able to quickly predict the behavior of the overall system—which includes actions of the L1 and L0 controllers in response to choices made by the L2 controller. From the viewpoint of the L2 controller, this can be achieved using one of the following strategies:
Simulate, at run time, the behavior of all lower-level controllers and components for various choices of surfaces (and sub-surfaces) being turned on/off. At the L2 layer, however, the size of the search space makes simulation-based optimization too costly to perform at run time.
Simulate the behavior of downstream components and controllers in an offline fashion as part of a supervised learning process, and then construct an approximation of the system dynamics to use at run time. For example, the L1 controllers can explicitly simulate the behavior of the underlying L0 controllers to construct the corresponding models. This, however, requires a very detailed model of the physical environment in which the surfaces have been placed, which may be impractical to obtain.

Behavior of the system components managed by the L1 and L0 control layers can be learned online as the system operates, and approximated by a suitable learning structure such as a neural network within the L2 controller. To further reduce the control overhead, approximation modeling techniques can be used to learn the behavior of the L2 controller as it adjusts the operating states of the surfaces in response to both the current performance and the complex dynamics of the lower-level control layers. To maintain validity of these models over the system's life time against slow behavioral changes to system components (due to configuration changes, failures, replacements, upgrades, etc.), adaptive learning strategies can be developed wherein the neural networks are trained continuously using feedback from the running system over a sliding window of data, to improve the accuracy of the initial models.

Reconfigurable intelligent surfaces (RISs) are an exciting new technology for next-generation wireless networks. While the electromagnetic propagation channel is generally considered to be an immutable black box, RIS provides the ability to modify the wireless channel in a manner that is beneficial to the overlying wireless system. The working principle of an RIS is analogous to two-dimensional phased array antennas. By selectively activating unit cells, the reflected signals (from RIS unit cells) add up constructively to a certain direction, enabling beam-steering capability. In an RIS, the power and phase distribution of the reflected signals (across the surface) are unknown to the controller. As a result, the RIS state selection can be considered a problem of driving a two-dimensional (2D) phased array without any information about the power and phase of the input signals at the array elements. Our work aims to offer a novel and pragmatic approach to obtaining the power and relative phase distribution throughout the RIS to better inform future state selection algorithms.

Provided is a new method of extracting incident power and relative phase distribution in an RIS by forming energy harvesting rectennas using RIS elements and rectifier circuits. Rectennas are simple and passive circuits consisting of a radio frequency (RF) matching network and a rectifier block with diodes, capacitors, and resistors in general. Rectennas have been extensively studied in recent years, mostly for achieving energy autonomy in wearable applications. They have the potential to contribute to the realization of the ubiquitous deployment of batteryless/passive Internet of Things (IoT) and green electronics. On the other hand, RISs have been at the forefront of the sixth generation (6G) of wireless research. The incorporation of energy harvesting components/rectifiers in RIS is a relatively new and unexplored research domain. Clerckx et al. proposed the use of rectennas with RIS for wireless information and power transfer applications

The combination of pre-selected RIS unit cells with RF-direct current (DC) conversion circuits can form rectennas for the estimation of incident power and relative phase distribution.

Four versions of the rectenna rectifier circuit have been developed, offering strong control of the spatial operating range and complexity of the circuit. The radiated power level of many mobile and IoT devices are low due to energy constraints and external restrictions. As a result, the power of the radio wave eventually reaching the RIS can be insufficient for some rectifier circuits. Thus, DC bias (or DC insertion alongside RF into the rectifier circuit) can be implemented to activate the rectifier circuit with low RF power levels. This results in a reduction of the input power threshold and enhancement in the sensitivity of the rectifier. Additionally, the availability of surface-mount and compact RF amplifiers makes them suitable for insertion into the RF-DC conversion circuits. The combination of DC bias and RF amplifier further increases the rectifier sensitivity.

RISs are mostly passive. As a result, it is difficult to acquire channel state information (CSI) from the RIS. Although rapid state selection is a fundamental requirement for the effective deployment of RIS, it is still a challenging and lengthy process. Optimization, machine learning, and digital twining have been proposed for RIS state selection. However, they require significant computational effort and environment-specific training. To realize the full benefit of RIS, it is important to have knowledge of the power and phase distribution of incident radio waves across the RIS. Although this information can be collected by deploying radios across the RIS, the overall system will be complicated and expensive, requiring synchronization and control. Our proposed method is flexible and inexpensive. The harvested energy map (or received power distribution) is readily available to the RIS controller which can be used for state selection based on the requirements.

The present disclosure paper proposes a new technique for EM design of RIS that leverages power-harvesting rectifier circuits sparsely distributed throughout the surface in addition to controllable reflectors such as those found in previous RIS designs. This design approach enables sensing capabilities that limit the state-selection search space by learning the incident power and phase of signals impinging on different parts of the surface to help determine the unit cells that would have the most impact on the metrics being optimized by the overlying RIS controller. Furthermore, the proposed RIS does not only function, conceptually, as a “mirror” to reflect the impinging signals but also as a programmable “lens” when the communicating nodes are on the opposite sides of the surface. Thus, our proposed RIS design does not require any ground plane, unlike many RIS prototypes in the literature, and each unit cell contains a voltage-controlled RF switch which allows for microwave transparency in the “off” state.

The operation of the RIS generally has two phases: 1) control and programming phase (to configure the RIS based on channel information) and 2) normal operation phase (when RIS has already been configured and ready to assist the trans-mission). Similar to the aforementioned prototypes, the RIS configuration optimization in the control and programming phase for application to wireless communications has vastly relied on analytics-based solutions (i.e., information theory, mathematical models, signal processing, and optimization algorithms). Although very successful, the traditional analytics-based approach to optimally configuring a very large array of RIS elements remains a challenge given the nearly-passive nature of the RIS (i.e., passively reflecting the incident waves) and the increased complexity of communication networks.

Due to recent advances in machine learning (ML) technology, especially in deep learning (DL), some researchers have combined model-based and data-driven approaches to overcome the inherent limitations. The authors in present a deep neural network (DNN) model that utilizes the sampled channel knowledge from active RIS elements as input to train the proposed DNN model offline to predict the optimal reflection beamforming matrix of the RIS in a supervised learning setting. Previously, a neural network-based method to configure the behavior of active RIS elements has been proposed. The wireless channel is modeled as a custom, interpretable, back-propagating neural network, where the RIS elements act as nodes and their cross-interactions as links. Thus, the neural network learns how to configure the RISs to improve communication performance once the training phase is complete.

Although ML and artificial intelligence (AI) may constitute efficient methods for optimally configuring the most appropriate operation of the RIS in the state-selection process, the training models in “big” data ML are both computationally and memory intensive. On the other hand, equipping the RIS surface with rectifiers as proposed in this paper to support the RIS state-selection process automatically reduces the computational burden by limiting the search space based on the knowledge of the power and phase of impinging waves.

### RIS Simulation

### RIS Design

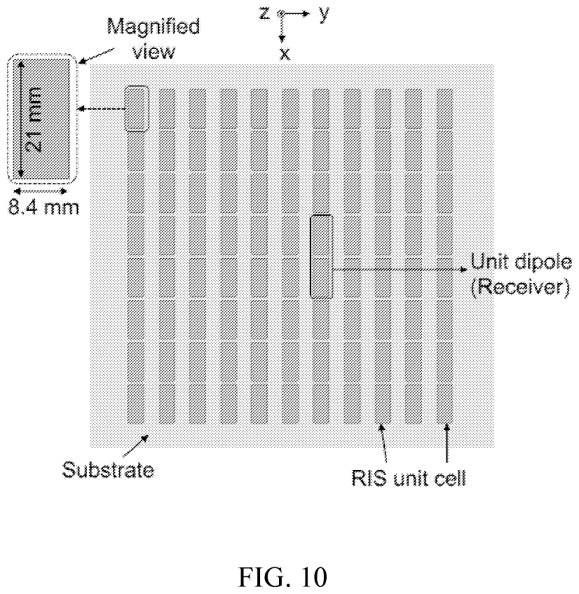

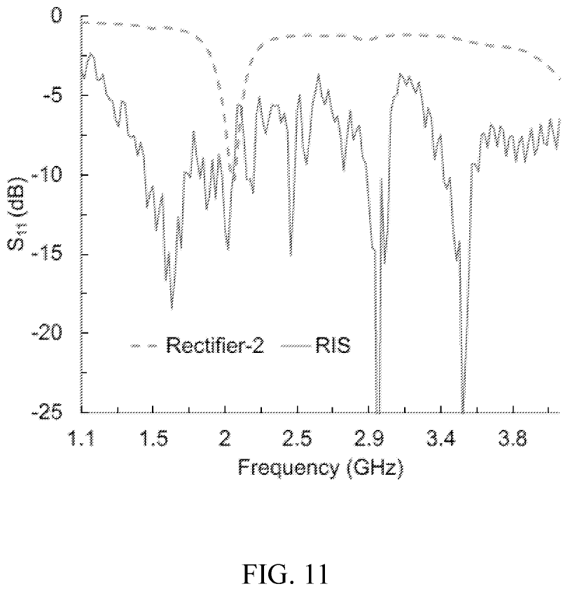

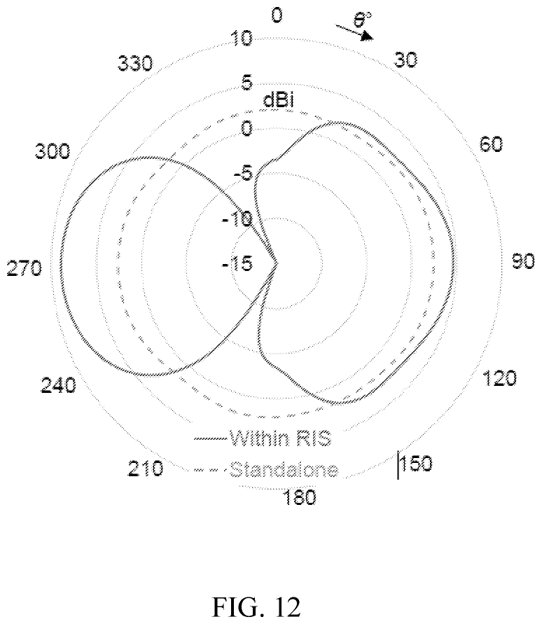

The RIS design (FIG. 10) is inspired by RFocus. An 8×11 RIS (FIG. 10) can be simulated and fabricated. Each rectangular tile measures 21 mm×8.4 mm. The tile length is approximately λε/4, where λε=effective wavelength due to the dielectric polyethylene substrate (relative permittivity, ε=2.25 in HFSS). Two adjacent RIS tiles form a dipole when they are connected (columnwise) by an RF switch. When all the RF switches are turned off, the RIS allows RF wave propagation and blocks when the switches are turned on. Selective activation of the RF switches converts the RIS structure into a phased array antenna where the input signal on each array element is the reflected signal. A lumped port can be placed between the 4th and 5th rows on the 7th column (FIG. 10). Each unit dipole is resonant at 2.1 GHz (FIG. 11). FIG. 12 shows the 2D radiation pattern of a unit dipole around the yz plane (azimuth in the experimental area). While a dipole in free space shows an omnidirectional radiation pattern, the RIS dipole pattern is heavily influenced by the parasitic presence of other unit cells around it.

### Angular Incidence Simulation

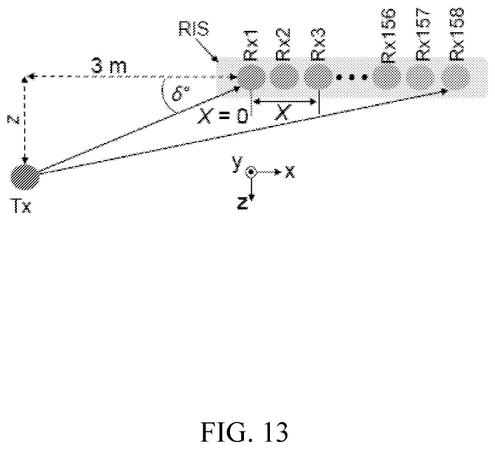

ne-dimensional Arrangement: A (2.1 GHz) RIS with 158-columns of unit cells along the x-axis (FIG. 13) can be simulated in MATLAB. The unit cell orientation and arrangement is identical to the RIS in FIG. 10. A transmitter (Tx) is 3 m away from the first receiver (Rx1) along the negative x-direction. Each receiver element (Rx1, Rx2, Rx3, . . . , Rx158) can demonstrate the 2D radiation pattern of the RIS unit cell shown in FIG. 12. The presence of two nulls (low gain zones) in the radiation pattern on both sides of the RIS can be seen. Although an ideal dipole would have an omnidirectional radiation pattern around its axis, the surrounding unit cells distort the radiation pattern of the unit dipoles in RIS.

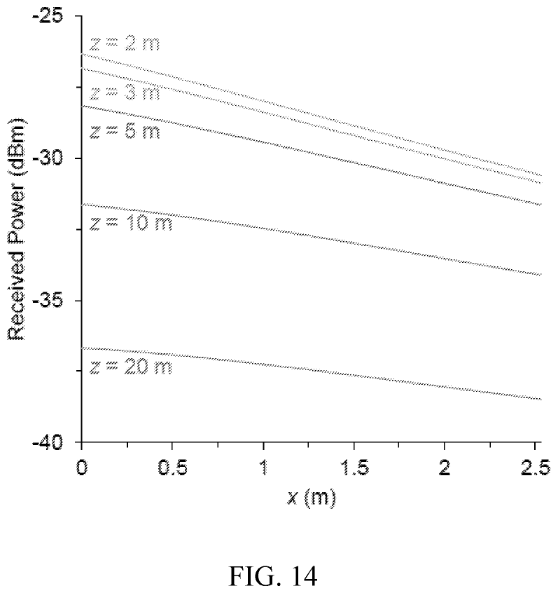

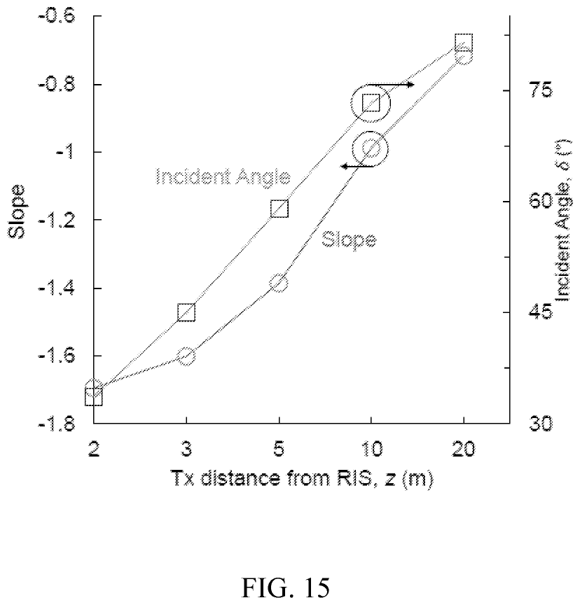

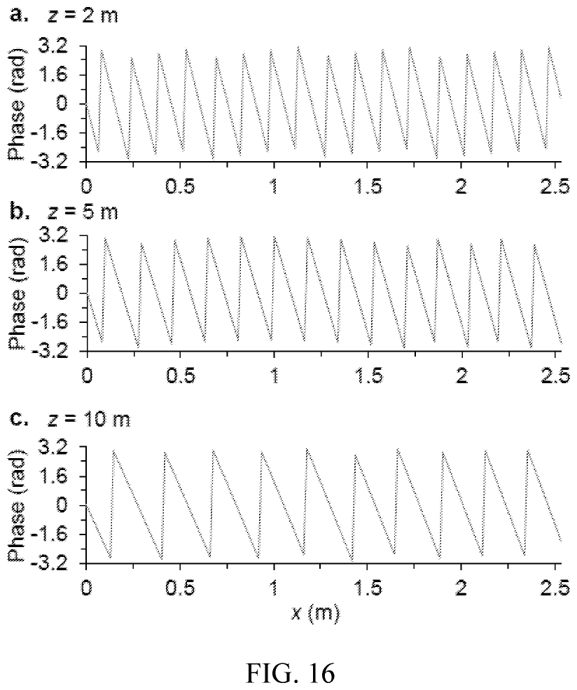

The power received by a receiver unit is calculated using the path equation:

$${P}_{tx} = {P}_{i n} + {G}_{tx} ( θ ) + {G}_{tx} ( θ ) + 20 {log}_{10} ( \frac{λ}{4 π r} ) \qquad ( 1 )$$

$$r = \sqrt{{( 3 + x )}^{2} + {z}^{2}} \qquad ( 2 )$$

where Pᵣₓ, Pᵢₙ, Gₜₓ, Gᵣₓ, λ, and θ indicate received power (dBm), input power (18 dBm), transmitter gain (8 dBi), receiver gain (dBi), wavelength (0.143 m at 2.1 GHz), angle of incidence, and the distance between the transceiver and the receiver (m), respectively. The power received by each element is shown in FIG. 14 for varying levels of normal distance (z) between the Tx and the RIS. The angle of incidence of the transmitted radio wave changes with z. For a wide range of z values, there can be a gradient in the received power. In other words, the received power is high for unit cells closer to the Tx and low for distant cells. The slope of the received power vs. x curve is plotted in FIG. 15. It is evident that the power distribution along the RIS is a function of the distance between the transmitter and the RIS. FIG. 16 shows the received signal phase variation for the receiver units.

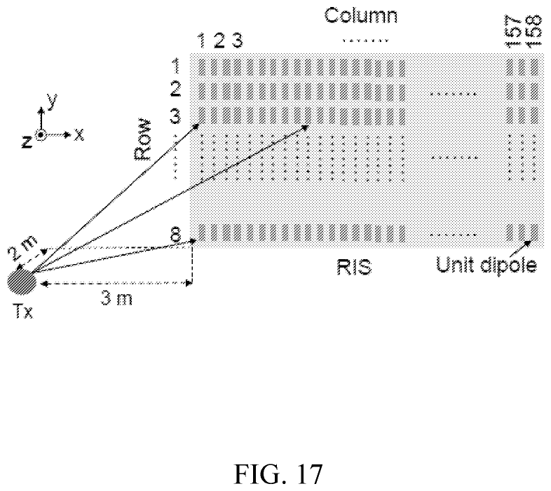

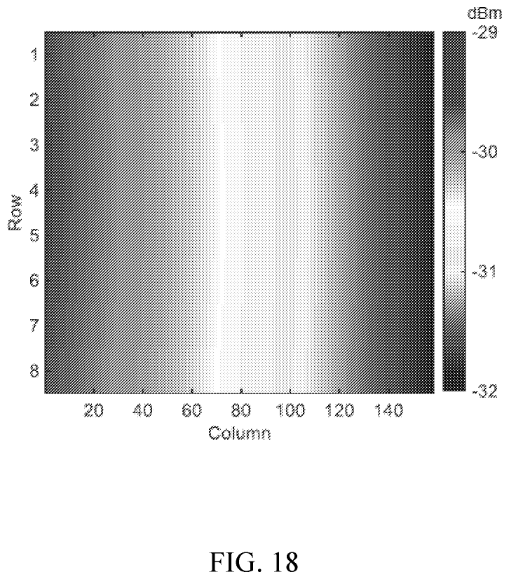

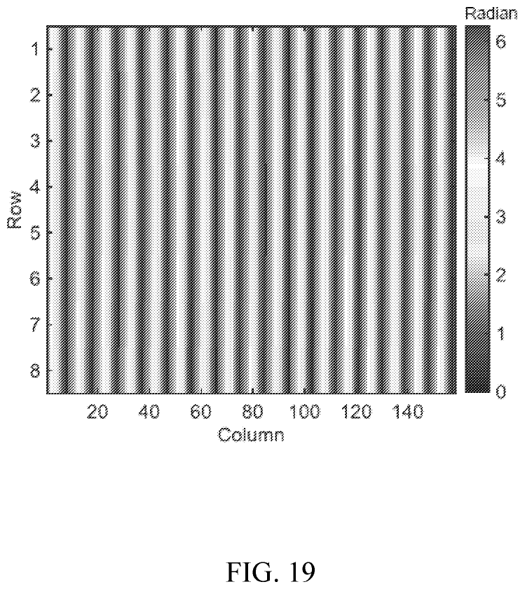

Two-dimensional Arrangement: A two-dimensional RIS with 8-rows and 158-columns is also simulated (FIG. 17) in Wireless Insite. Similar to the 1D arrangement, the received power diminishes along the x-direction as the separation between the Tx and the unit dipoles increases (FIG. 18). The phase of the received signal demonstrates a periodic pattern along the x-axis (FIG. 19).

Prior knowledge of the received power phase distribution along the RIS unit cells can greatly benefit the state-selection procedure of RIS. The phase distribution is dependent on the DoA of the transmitter signal. Therefore, the fundamental proposition of our work is established. The received RF power can be converted to DC using different approaches through experimentation.

### Experimental Setup

### Rectifier Design

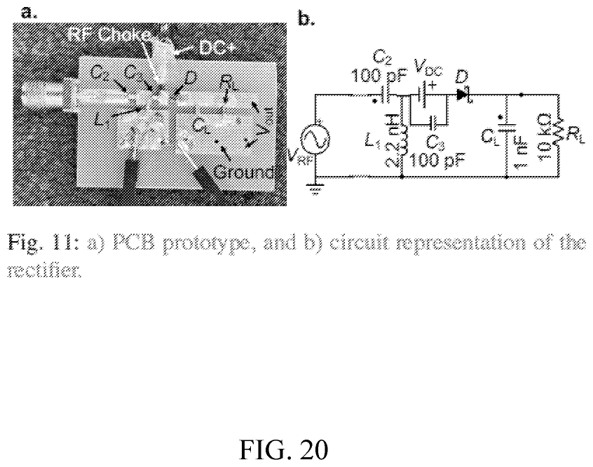

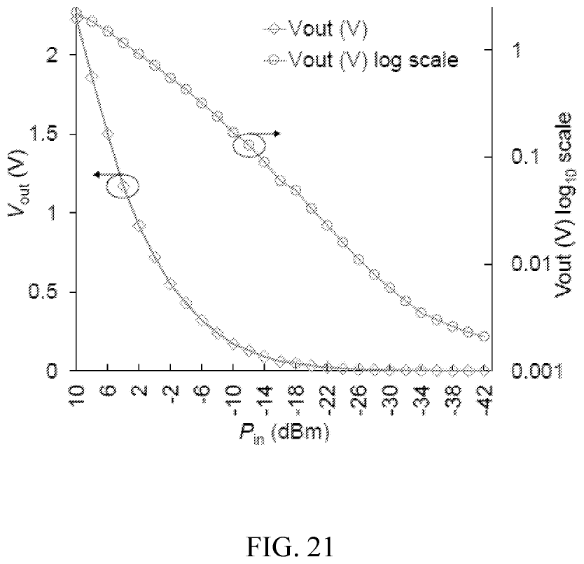

The rectifier (FIG. 20) is fabricated on a 1.6 mm thick FR4 substrate. A 50Ω sub-miniature version A (SMA) connector connects the rectifier with the receiver antenna. The incoming RF signal passes through a matching network consisting of a series capacitor (C₂=100 pF) and a parallel inductor (L₂=2.2 nH). A Schottky diode (D, model: MA4E20541-1141T) in series converts the RF signal to DC. The rectified DC power is stored in the load capacitor (C_{L}) that is charged during the positive cycle and feeds the load resistor (R_{L}) during the negative cycle. An additional capacitor C₃ sits between C₂ and the Schottky diode D. A variable DC voltage source VDC is placed across C₃. Two 220 nH inductors are used as RF chokes for blocking the RF signal from traveling into the DC circuit. The DC ground is connected to the RF ground through L₁. C₂ and C₃ block any DC component from flowing toward the RF source (or the receiver antenna). FIG. 11 shows the reflection coefficient (S₁₁) of the rectifier as a function of frequency. The Rectifier is resonant at 2.1 GHz. FIG. 21 shows the rectifier output voltage vs. input power (at the rectifier port) plot. The intrinsic sensitivity of the rectifier is −42 dBm. In other words, the rectifier can detect radio waves stronger than −42 dBm.

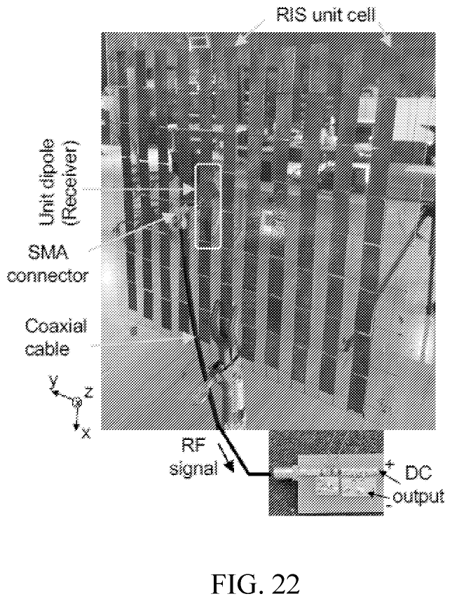

Due to the nonlinear nature of diodes, the rectifier also demonstrates nonlinearity in FIG. 21. For a given rectifier—RIS combination, the input RF power can be obtained from a lookup table (FIG. 21) saved in the controller unit. FIG. 22 shows the fabricated prototype of the RIS along with the rectifier. A coaxial cable (with SMA connectors) connects the unit dipole and the rectifier.

### RF Energy Harvesting

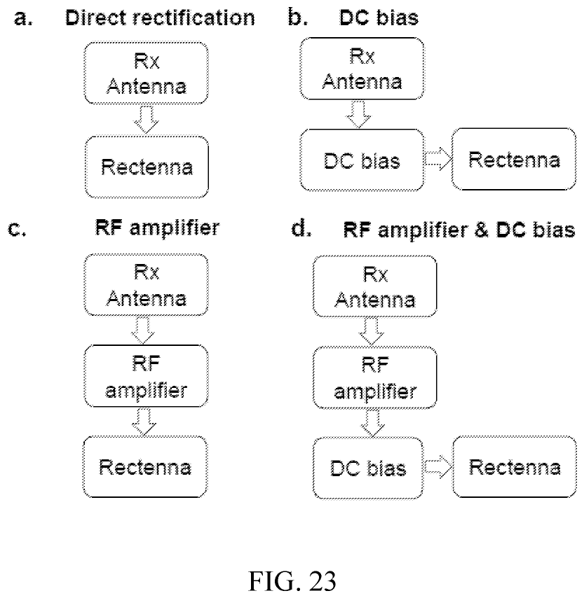

The effectiveness of the proposed system is strongly de-pendent on the sensitivity of the energy harvesting circuit (rectifier). Four methods (FIG. 23) of received power rectification are proposed:

Direct Rectification: The power received by the RIS unit pair dipole is directly fed to the rectifier circuit and converted to DC. While this is the simplest approach, the sensitivity of the system is low and the effective range is the lowest of the considered techniques.

Rectification with DC Bias: The power required to activate the Schottky diode is the limiting factor in the RF-DC conversion. If the input RF power level is insufficient for diode activation, it is possible to bias the diode by inserting a small amount of DC voltage (12.7 mV in our experiment) in the rectifier circuit. The effective range is higher than direct rectification. For identical reception scenarios, the rectifier output level will be higher with DC bias compared to direct rectification, reducing the burden on the sensitivity of the controller (typically microcontrollers).

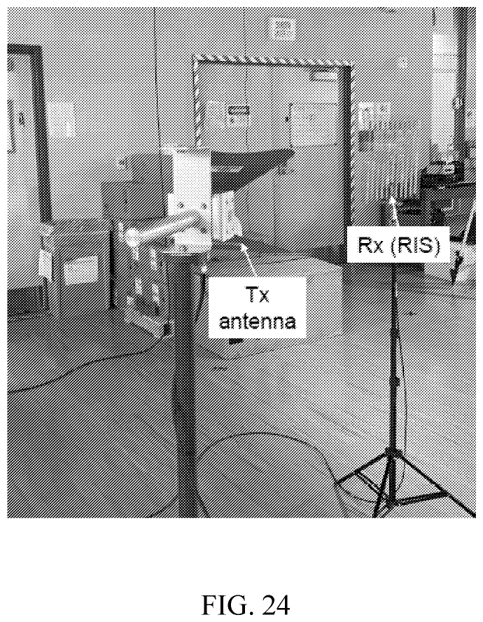

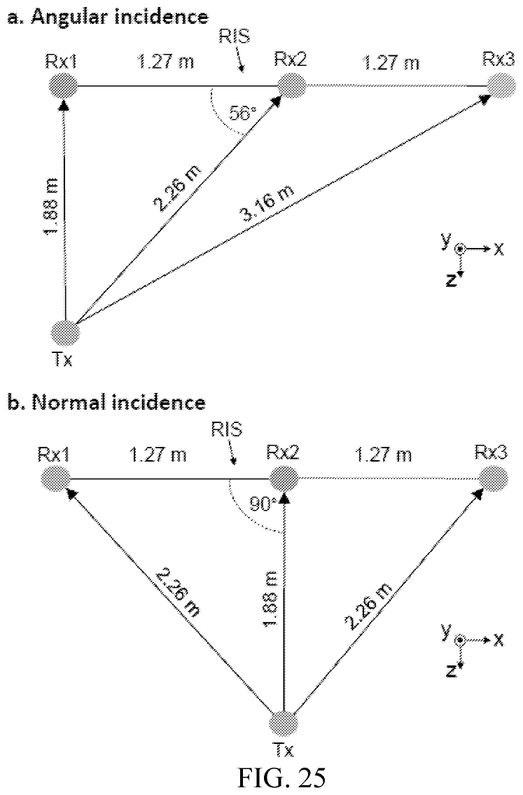

FIG. 24 and FIG. 25 show the experimental setup in a large indoor environment. A 2.1 GHz double ridge horn antenna with a maximum gain of 8 dBi was used as the transmitter. The separation between the Tx and Rx was chosen to ensure that both antennas are in each other's far-field. The far-field distance of the transmitter (horn) antenna is greater than 0.33 m at 2.1 GHz. The minimum distance between the Tx-Rx (Tx2, Rx1 pair) is larger than the far field distance of the larger antenna (transmitter horn). Since most radio antennas in real life are omnidirectional, the transmitter horn can be focused towards the RIS (Rx). In other words, the transmitter was effectively an 8 dBi omnidirectional radiator.

An SMA connector connecting two unit cells form a diode that was used as the receiver. Both the transmitter and the receiver were used in vertical polarization, 1.2 m from the ground. The transmitter was placed in two different positions (Tx1 and Tx2), and the receiver was placed in three positions (Rx1, Rx2, and Rx3). An RF signal generator fed the transmitter with a constant 18 dBm power (continuous wave). The receiver (RIS unit cell diode) was connected to the rectifier through a coaxial cable. For each Tx-Rx pair, the received power was measured using a spectrum analyzer and the rectified voltage level (at the rectifier output) was measured with a multimeter.

Two rounds of experiments can be conducted—i) angular incidence: when the radio wave is incident at an acute angle with the center of the RIS, and ii) normal incidence: when the radio wave is incident perpendicularly on the center of the RIS.

### Results and Discussion

Energy Harvesting from RIS

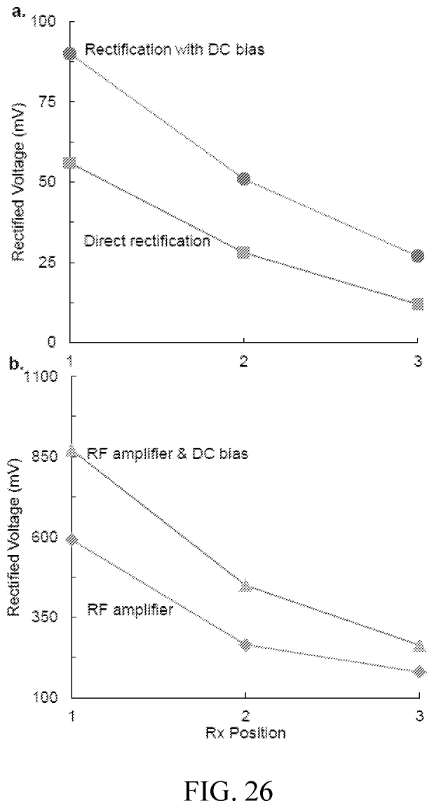

FIG. 26 shows the rectified (harvested) voltage from the angular incidence of the radio waves on the RIS. The direct rectification method yields minimum DC output. With the insertion of 12.7 mV DC bias voltage, the output voltage level is improved significantly (more than 12.7 mV). The improvement in DC output (FIG. 26a) with a small bias voltage is not uniform at the receiver positions due the non-linearity of the Schottky diode. In other words, since the IV (current-voltage) curve of a Schottky diode is non-linear, the current through the diode will depend on the input voltage. As a result, the current through the load varies with the input power level, resulting in different levels of improvement in the rectified voltage (based on receiver locations). The elevated output power level increases the range of the system and relaxes the restrictions (for scenarios identical to direct rectification) on the sensitivity of the DC detector on the controller side.

The RF amplifier (15 dB) improves the rectified voltage level more than 10-times. The RF amplifier enhances the range of the proposed system by increasing the sensitivity. The RF amplifier and DC bias combination produce the maximum output. It is also clear that the DC insertion creates uneven improvement (FIG. 26b) in rectified voltage that is also seen in FIG. 26a.

### Power and Relative Phase Distribution

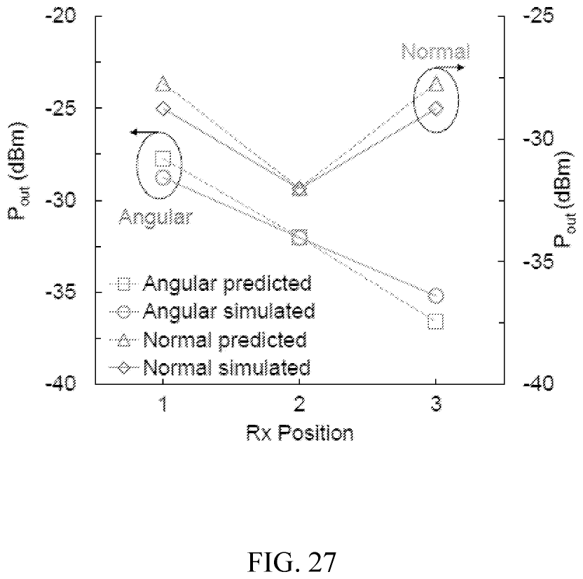

The power levels and the pattern of the power distribution (at the receiver locations) can be predicted for both angular and normal incidences (FIG. 27). The rectified voltage outputs are mapped (predicted) into output power using FIG. 21. The RIS comprises of thousands of switchable unit dipoles. It would be infeasible to accommodate energy harvesting units for each unit. However, it would be possible to predict the overall power and phase distribution around the RIS by placing a limited number of energy harvesting units.

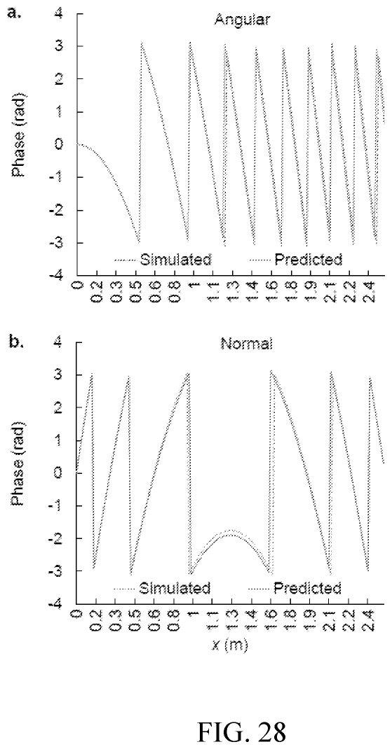

FIG. 28 shows a comparison between the simulated and predicted relative phase distribution for angular and normal incidence (depicted in FIG. 25a).

### RIS State-Selection

The proposed system can facilitate the existing RIS state-selection algorithms. A rectifier-assisted RIS state-selection algorithm can be developed using the following steps:

First, the radio signal is incident on the RIS.

Sparsely distributed rectifier circuits convert the incident radio energy into DC voltage (Vₒᵤₜ) using any of the four proposed methods.

The RIS switch controller obtains the distribution of Vₒᵤₜ. A Vₒᵤₜ to Pₒᵤₜ chart (similar to FIG. 21) is used to convert the DC voltage distribution to received RF power distribution.

At this step, the RIS unit dipoles are considered the elements of a 2D array of antennas. The input power of each array element would be known by subtracting the Ohmic and dielectric loss in the antenna (can be considered uniform for all elements, except for peripheral elements) from the Pₒᵤₜ values.

The RIS controller decides the switching combination to steer the reflected beam to the desired direction. The RIS state-selection problem is thus converted to a much simpler and more deterministic phased array switching problem.

Simulated and practical power and phase relations will not match accurately due to the dynamic nature of practical channels and the limitation of simulation. Therefore, a learning-based algorithm can be developed for the state-selection problem. Channel emulation and transfer learning can also be advantageous for a rapid state selection and a seamless integration of the RIS to the network.

The presence of multipath components will impact the power distribution in the RIS. Nevertheless, the energy harvesting circuit will still be able to detect the power distribution throughout the surface. In this experiment, one RIS is considered, whereas, in a practical scenario, multiple RISs will work in conjunction. It has been shown that the multipath fading effect can be eliminated when all reflectors in the environment are coated with RIS.

### CONCLUSION

In summary, the applicability of energy harvesting rectifiers for estimating incident power and relative phase mapping across RISs is described. The proposed method can potentially simplify and speed up the state-selection process for RIS. Using a combination of simulation and experimentation, the received power distribution across an RIS can be predicted from the harvested energy levels. One of the limitations of the proposed method is the presence of nulls in the radiation pattern of the unit dipoles in the RIS. However, it is possible to acknowledge the impact of the null by incorporating machine learning algorithms. Incident power mapping in 1D and 2D RISs can be demonstrated. In the future, the implementation of the proposed technique in state-selection algorithms can be demonstrated.

It will be apparent to those of ordinary skill in the art that variations and alternative embodiments may be made given the foregoing description. Such variations and alternative embodiments are accordingly considered within the scope of the present invention.

Joinder references (e.g., attached, coupled, connected, joined, and the like) are to be construed broadly and may include intermediate members between a connection of elements and relative movement between elements. As such, joinder references do not necessarily infer that two elements are directly connected and in fixed relation to each other.

The above specification, examples and data provide a complete description of the structure and use of exemplary embodiments of the invention. Although various embodiments of the invention have been described above with a certain degree of particularity, or with reference to one or more individual embodiments, those skilled in the art could make numerous alterations to the disclosed embodiments without departing from the spirit or scope of this invention. Other embodiments are therefore contemplated. It is intended that all matter contained in the above description and shown in the accompanying drawings shall be interpreted as illustrative only of particular embodiments and not limiting. Changes in detail or structure may be made without departing from the basic elements of the invention as defined in the following claims.

What is claimed:

1. A reconfigurable intelligent surface (RIS) for controlling propagation in a communication system, the RIS comprising:
a plurality of switches;
a first plurality of conductive fabrics, wherein each one of the first plurality of conductive fabrics is connected to another one of the first plurality of conductive fabrics by a switch of the plurality of switches;
a second plurality of conductive fabrics, wherein each one of the second plurality of conductive fabrics is connected to another of the second plurality of conductive fabrics by one switch of the plurality of switches; and
a non-conductive fabric layer, wherein the first plurality of conductive fabrics and the second plurality of conductive fabrics are attached to the non-conductive fabric layer, the first plurality of conductive fabrics being spaced from the second plurality of conductive fabrics.

2. The RIS of claim 1, wherein each of the first plurality of conductive fabrics includes a knitted pocket, each knitted pocket including one of the plurality of switches attached thereto.

3. The RIS of claim 1, wherein each of the plurality of switches is wirelessly controlled by the communication system.

4. The RIS of claim 1, further comprising:
a control fabric layer that includes a plurality of conductive threads configured to carry control signals to the plurality of switches.

5. The RIS of claim 4, wherein the control fabric layer is attached to the non-conductive fabric layer.

6. The RIS of claim 1, wherein both of the first plurality of conductive fabrics and the second plurality of conductive fabrics are knitted to the non-conductive fabric layer.

7. The RIS of claim 1, wherein both of the first plurality of conductive fabrics and the second plurality of conductive fabrics comprise knitted conductive fabrics.

8. A communication system comprising:
a reconfigurable intelligent surface (RIS) comprising:
a plurality of switches,
a first plurality of conductive fabrics, wherein each one of the first plurality of conductive fabrics is connected to another one of the first plurality of conductive fabrics by one switch of the plurality of switches,
a second plurality of conductive fabrics, wherein each one of the second plurality of conductive fabrics is connected to another one of the second plurality of conductive fabrics by one switch of the plurality of switches, and
a non-conductive fabric layer, wherein the first plurality of conductive fabrics and the second plurality of conductive fabrics are attached to the non-conductive fabric layer, the first plurality of conductive fabrics being spaced from the second plurality of conductive fabric; and
a controller configured to transmit control signals to the plurality of switches to control propagation.

9. The communication system of claim 8, wherein both of the first plurality of conductive fabrics and the second plurality of conductive fabrics are knitted to the non-conductive fabric layer.

10. The communication system of claim 8, wherein the controller transmits the control signals to the plurality of switches to affect an impedance of the RIS.

11. The communication system of claim 8, further comprising:
a transmitter configured to transmit a signal; and
a receiver configured to receive the signal via the RIS.

12. The communication system of claim 8, wherein the RIS is integrated into at least one of a drape, a wall covering, an upholstery, and a carpet.

13. An intelligent system, comprising:
a reconfigurable intelligent surface (RIS),
the RIS comprising at least one energy harvesting circuit.

14. The intelligent system of claim 13, wherein the energy harvesting circuit comprises a rectifier.

15. The intelligent system of claim 14, wherein the rectifier operates according to any one or more of (i) direct rectification, (ii) rectification with DC bias, and (iii) rectification with a radio frequency (RF) amplifier.

16. The intelligent system of claim 13 wherein the energy harvesting circuit comprises a rectenna.

17. The intelligent system of claim 16, wherein the rectenna comprises a unit cell of the RIS and a RF-direct current (DC) conversion circuit.

18. The intelligent system of claim 16, further comprising a DC bias and/or DC insertion associated with the rectifier.

19. An intelligent system, the intelligent system comprising a RIS as described herein.

20. A method, comprising developing a harvested energy map or received power distribution of an intelligent system according claim 1.

21. The method of claim 20, further comprising selecting a state of the intelligent system based at least in part on the harvested energy map or received power distribution of the intelligent system.
